(19) United States
(12) Patent Application Publication
(10) Pub. No.: US 2024/0413066 A1
(43) Pub. Date: Dec. 12, 2024

(54) EMBEDDED SEMICONDUCTOR DEVICE

(71) Applicant: Intel Corporation, Santa Clara, CA (US)

(72) Inventors: Ranjul BALAKRISHNAN, Bangalore (IN); Sandesh GEEJAGAARU KRISHNAMURTH, Bangalore (IN); Parnasree MAITI, Bangalore (IN)

(21) Appl. No.: 18/331,964

(22) Filed: Jun. 9, 2023

(51) Int. Cl. H01L 23/498; H01L 21/48; H01L 23/00; H01L 23/552

(52) U.S. Cl. CPC H01L 23/49822; H01L 21/4817; H01L 23/552; H01L 24/16; H01L 24/32; H01L 24/73; H01L 24/81; H01L 2224/16225; H01L 2224/32225; H01L 2224/73204; H01L 2224/81192; H01L 2924/1616; H01L 2924/16235

(57) ABSTRACT

According to various examples, a device is described. The device may include a package substrate. The device may also include a dielectric underfill layer disposed above the package substrate, wherein the package substrate comprises an embedded microstrip layer embedded in the dielectric underfill layer. The device may also include a semiconductor device embedded in the dielectric underfill layer and electrically coupled to the embedded microstrip of the package substrate. The device may also include an electromagnetic interference absorber above a top surface of the semiconductor device, wherein the semiconductor device is electrically coupled to the embedded microstrip layer of the package substrate.

### TECHNICAL FIELD

Various aspects relate to an embedded semiconductor device, a computer device and a method of forming the embedded semiconductor device.

### BACKGROUND

Conventional semiconductor devices use microstrip routing on package substrates to reduce package layer count and package height. In client packages, the substrate layer counts are usually dictated by Double Data Rate (DDR) memory routing. Normally the substrate layer counts in packages are 10 layers with the DDR interface occupying 2 stripline routing layers at the upper half side of stackup itself. The total layer count in the substrate directly impacts the cost and height (Z) of the package. In order to control the cross talk, DDR bus traditionally demands stripline routing on the package Core front side. The bottom half of the package layers are usually routed with power and ground rails sandwiched for best power delivery design. Sometimes, limited back side routing is done for DDR signals but early transition to back side will not be feasible due to difficulty of placing large size plated through holes (PTH) close to the die edge.

An existing solution is to make use of microstrip layer for one of the DDR channels to enable microstrip and stripline combinations which help to reduce the total substrate layers to 8 layers. However, routing high-speed signals for example Double Data Rate (DDR) memory or single-ended signals on microstrip layer will result in multiple problems such as high crosstalk

(FEXT) especially very high inductive far end cross talk. Due to the proximity of air (Er=1) lower distributed capacitance in the transmission lines results higher impedance and to achieve desired impedance usually requires very large trace widths. Once trace width increased, due to the physical real estate constraint, spacing between the DDR signals reduces and that increases the signal cross talk further. Due to high cross talk, DDR performance is compromised for 1 or 2 speed bins lower. Moreover, differential signals suffer high mode conversion from differential to common mode due to the velocity difference between even mode and odd mode. Further, microstrip structures are a major source of electromagnetic interference (EMI).

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of an embedded device according to an aspect of the present disclosure;

FIG. 2 shows a flow chart illustrating a method of forming an embedded device according to an aspect of the present disclosure;

FIG. 3A shows a conventional semiconductor device while FIG. 3B shows an exemplary embedded device according to an aspect of the present disclosure;

FIG. 4A shows a conventional microstrip stackup while FIG. 4B shows an exemplary embedded microstrip according to an aspect of the present disclosure;

FIGS. 5A to 5C show crosstalk and EMI results of the semiconductor device of FIG. 1;

FIG. 6 shows an illustration of a computing device that includes a semiconductor package according to a further aspect of the present disclosure.

### DETAILED DESCRIPTION

The following detailed description refers to the accompanying drawings that show, by way of illustration, specific details and aspects in which the disclosure may be practiced. One or more aspects are described in sufficient detail to enable those skilled in the art to practice the disclosure. Other aspects may be utilized and structural, logical, and/or electrical changes may be made without departing from the scope of the disclosure. The various aspects of the disclosure are not necessarily mutually exclusive, as some aspects can be combined with one or more other aspects to form new aspects or embodiments. Various aspects are described in connection with methods and various aspects are described in connection with devices. However, it may be understood that aspects described in connection with methods may similarly apply to the devices, and vice versa.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The words “plural” and “multiple” in the description and in the claims expressly refer to a quantity greater than one. Accordingly, any phrases explicitly invoking the aforementioned words (e.g., “a plurality of (objects)”, “multiple (objects)”) referring to a quantity of objects expressly refer to more than one of the said objects. The terms “group (of)”, “set (of)”, “collection (of)”, “series (of)”, “sequence (of)”, “grouping (of)”, etc., and the like in the description and in the claims, if any, refer to a quantity equal to or greater than one, i.e. one or more.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art. Any type of information, as described herein, may be handled for example via one or more processors in a suitable way, e.g. as data.

The terms “processor” or “controller” as, for example, used herein may be understood as any kind of entity that allows handling data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

The term “module” detailed herein refers to, or forms part of, or includes an Application Specific Integrated Circuit (ASIC); an electronic circuit; a combinational logic circuit; a field programmable gate array (FPGA); a processor (shared, dedicated, or group) that executes code; other suitable hardware components that provide the described functionality; or a combination of some or all of the above, such as in a system-on-chip. The term module may include memory (shared, dedicated, or group) that stores code executed by the processor.

A processor, controller, and/or circuit detailed herein may be implemented in software, hardware, and/or as a hybrid implementation including software and hardware.

The term “system” (e.g., an artificial intelligence system, a machine learning system, a computing system, etc.) detailed herein may be understood as a set of interacting elements, of which the elements can be, by way of example and not of limitation, one or more mechanical components, one or more electrical components, one or more instructions (e.g., encoded in storage media), and/or one or more processors, and the like.

The term “semiconductor die” as used herein refers to both the singular and plural form of the words, and accordingly can refer to both a single semiconductor device and multiple semiconductor devices.

The term “semiconductor substrate” detailed herein may include an organic package substrate, a coreless substrate, and a high-density build-up (HDBU) laminate substrate, and may be organic, or made of glass.

An advantage of the present disclosure may include improved or reduced cross talk by application of a dielectric layer.

An advantage of the present disclosure may include controlled EMI through application of an EMI absorber.

These and other aforementioned advantages and features of the aspects herein disclosed will be apparent through reference to the following description and the accompanying drawings. Furthermore, it is to be understood that the features of the various aspects described herein are not mutually exclusive and can exist in various combinations and permutations.

The present disclosure generally relates to a device. The device may include a package substrate. The device may also include a dielectric underfill layer disposed above the package substrate, wherein the package substrate comprises an embedded microstrip layer embedded in the dielectric underfill layer. The device may also include a semiconductor device embedded in the dielectric underfill layer and electrically coupled to the embedded microstrip of the package substrate. The device may also include an electromagnetic interference absorber above a top surface of the semiconductor device, wherein the semiconductor device is electrically coupled to the embedded microstrip layer of the package substrate.

The present disclosure generally relates to a method of forming a device. The method may include providing a package substrate. The method may also include forming a dielectric underfill layer above the package substrate, wherein the package substrate comprises an embedded microstrip layer embedded in the dielectric underfill layer. The method may also include embedding a semiconductor device in the dielectric underfill layer and electrically coupling the semiconductor device to the embedded microstrip of the package substrate. The method may also include providing an electromagnetic interference absorber above a top surface of the semiconductor device, wherein the semiconductor device is electrically coupled to the embedded microstrip layer of the package substrate.

The present disclosure generally relates to a computing device. The computing device may include a printed circuit board. The computing device may include a semiconductor package coupled to the printed circuit board. The semiconductor package may include a package substrate. The semiconductor package may also include a dielectric underfill layer disposed above the package substrate, wherein the package substrate comprises an embedded microstrip layer embedded in the dielectric underfill layer. The semiconductor package may also include a semiconductor device embedded in the dielectric underfill layer and electrically coupled to the embedded microstrip of the package substrate. The semiconductor package may also include an electromagnetic interference absorber above a top surface of the semiconductor device, wherein the semiconductor device is electrically coupled to the embedded microstrip layer of the package substrate.

To more readily understand and put into practical effect, the present device, computing device, method, and other particular aspects will now be described by way of examples and not limitations, and with reference to the figures. For the sake of brevity, duplicate descriptions of features and properties may be omitted.

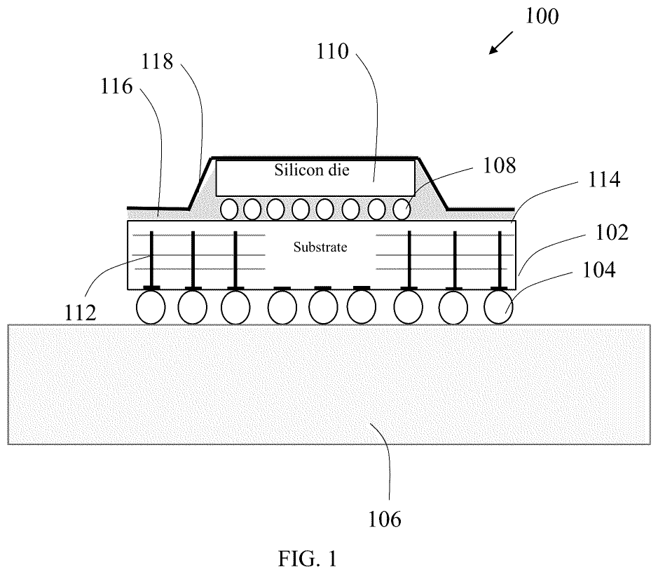

FIG. 1 shows a cross-sectional view of an embedded device according to an aspect of the present disclosure.

In an aspect of the present disclosure, a semiconductor package 100 is shown in FIG. 1. The semiconductor package 100 may be an embedded device. The semiconductor package 100 may be a stacked semiconductor package like a 2.5D or a 3D semiconductor package.

In an aspect of the present disclosure, the semiconductor package 100 may include a package substrate 102. The package substrate 102 may include contact pads, electrical interconnects, routings, and other features, which are not shown in any of the present figures. The package substrate 102 may have one or more rigid core layer for improved structural stability or a coreless substrate package for a reduced form-factor. In other aspects, the package substrate 102 may be part of a larger substrate that supports additional semiconductor packages, and/or components.

In an aspect of the present disclosure, the semiconductor package 100 may include a plurality of solder balls 104. In an aspect, the plurality of solder balls 104 may be disposed on a bottom surface of the package substrate 102. The package substrate 102 may be connected to a motherboard 106 through the plurality of solder balls 104. The motherboard 106 may be a PCB. In an aspect, the plurality of solder balls 104 may provide an electrical connection between the package substrate 102, and the motherboard 106.

In an aspect of the present disclosure, the semiconductor package 100 may include a plurality of package bumps 108 the plurality of package bumps 108 may be C4 bumps.

In an aspect of the present disclosure, the semiconductor package 100 may include a semiconductor device 110. In an aspect, the semiconductor device 110 may be made from any suitable semiconductor, such as silicon or gallium arsenide. The semiconductor device 110 may be a semiconductor die, a chip or a set of chiplets, e.g., a system-on-chip (SOC). The plurality of package bumps 108 may be disposed between the package substrate 102 and the semiconductor device 110 for electrical connection between the package substrate 102 and the semiconductor device 110.

In an aspect of the present disclosure, the semiconductor package 100 may include a plurality of interconnects 112. In an aspect, the plurality of interconnects 112 may be disposed or embedded in the package substrate 102. In an aspect, the plurality of interconnects 112 may be coupled to the semiconductor device 110 through the plurality of package bumps 108.

In an aspect of the present disclosure, the package substrate 102 is configured to transmit signals to the plurality of semiconductor devices 110 through the plurality of interconnects 112.

In an aspect of the present disclosure, the package substrate 102 may include an embedded microstrip layer configured for high speed signal routing with the semiconductor device. The embedded microstrip layer may be configured for Double Data Rate (DDR) memory signal routing.

In an aspect of the present disclosure, the semiconductor package 100 may include a surface layer 114 on a top surface of the package substrate 102. A dielectric underfill layer 116 may be formed on the surface layer 114 of the package substrate 102. The dielectric underfill layer 116 may be a nonconductive epoxy layer. In an aspect of the present disclosure, the dielectric underfill layer 116 is formed to cover the full surface layer 114 of the package substrate 102. The dielectric underfill layer 116 is also disposed around the semiconductor device 110 edges, for example the sides of the semiconductor device 110. The semiconductor device 110 is embedded in the dielectric underfill layer 116. A top surface of the semiconductor device 110 may be covered with an electromagnetic interference absorber 118.

In an aspect of the present disclosure, the package substrate 102 may include an embedded microstrip layer which is embedded in the dielectric underfill layer 116.

In an aspect of the present disclosure, the dielectric underfill layer 116 may have a thickness of around 10-40 um, for example 20 um thickness.

In an aspect of the present disclosure, the semiconductor package 100 may include the electromagnetic interference absorber 118 which is above a top surface of the semiconductor device 110. In an aspect, the electromagnetic interference absorber 118 may be in contact with the top surface of the semiconductor device 110. In another aspect, the electromagnetic interference absorber 118 may not be in contact with the top surface of the semiconductor device 110. For example, there may be a layer of dielectric underfill layer betwwen the electromagnetic interference absorber 118 and the top surface of the semiconductor device 110.

The electromagnetic interference absorber 118 may comprises graphene, for example a functionalized graphene epoxy layer, which may comprise 15% of graphene by weight. The electromagnetic interference absorber 118 may have a thickness of between 100 to 200 um. The electromagnetic interference absorber 118 may be coated to cover top side of the semiconductor device 110 and the dielectric underfill layer 116.

In an aspect of the present disclosure, the embedded microstrip significantly nullify the far end cross talk compared to conventional microstrip as the top layer is filled with dielectric material with larger Er value (˜3.8) compared to the Air with Er=1.

In an aspect of the present disclosure, due to the proximity of dielectric material, higher distributed capacitance in the transmission lines helps to reduce the impedance notable compared to the regular microstrip structures and helps to reduce the trace width without compromising the trace to trace spacing for a given routing real estate and that reduces the signal cross talk.

In an aspect of the present disclosure, differential signal quality is improved due to the well-balanced velocity between even mode and odd mode, significantly nullifying the mode conversion compared to regular microstrip structure.

In an aspect of the present disclosure, due to overall improved or reduced far end cross talk, DDR performance is well improved in an 8 layer package compared to regular microstrip structure. Dielectric addition can be conducted in selective area without changing the overall stackup so, other interfaces are un-disturbed, do not need any physical and electrical re-design.

In an aspect of the present disclosure, there may be substantial EMI benefits after shielding is introduced. Since the shielding material is introduced at certain controlled height (>>100 um), signal transmission is not impacted.

In an aspect of the present disclosure, since graphene is a heat conductor, graphene deposition on surface of the die & substrate will spread heat from the semiconductor device 110 resulting in thermal benefits for the semiconductor package 100.

In an aspect of the present disclosure, the electromagnetic interference absorber 118 applied over the semiconductor package 100 does not need to be grounded, which makes this simple to implement.

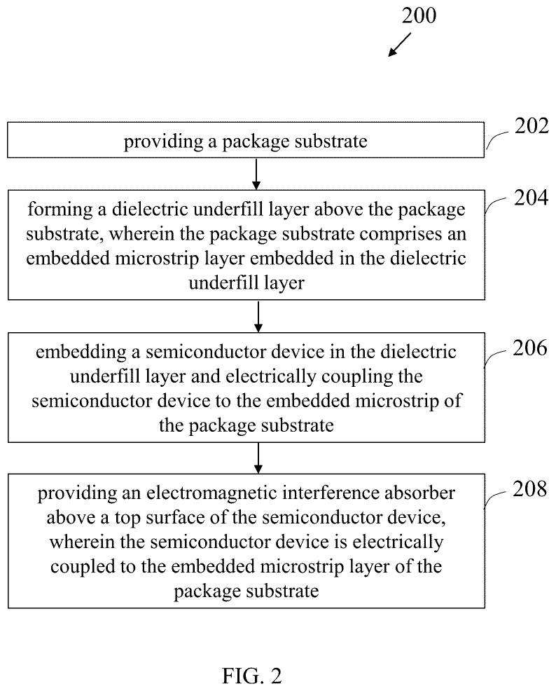

FIG. 2 shows a flow chart illustrating a method of forming an embedded device according to an aspect of the present disclosure.

As shown in FIG. 2, there may be a method 200 of forming a device. In the method 200, a first operation 202 may include providing a package substrate. A second operation 204 may include forming a dielectric underfill layer above the package substrate. A third operation 206 may include embedding a semiconductor device in the dielectric underfill layer, wherein the semiconductor device is electrically coupled to the package substrate.

It will be understood that the above operations described above relating to FIG. 2 are not limited to this particular order. Any suitable, modified order of operations may be used.

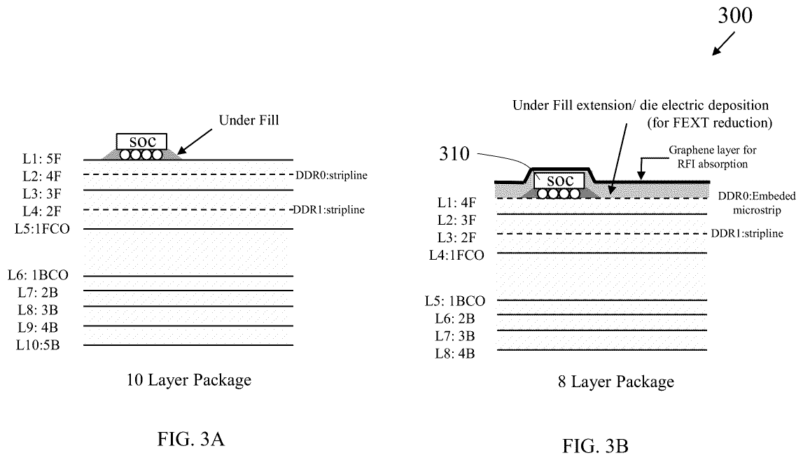

FIG. 3A shows a conventional semiconductor device while FIG. 3B shows an exemplary embedded device according to an aspect of the present disclosure.

As shown in FIG. 3B, embedded device 300 includes a semiconductor device 310 which is embedded by a dielectric layer according to an aspect of the present disclosure. This results in a reduced package layer count and reduced package height while reducing crosstalk and electromagnetic interference from the microstrip compared to the conventional design of FIG. 3A.

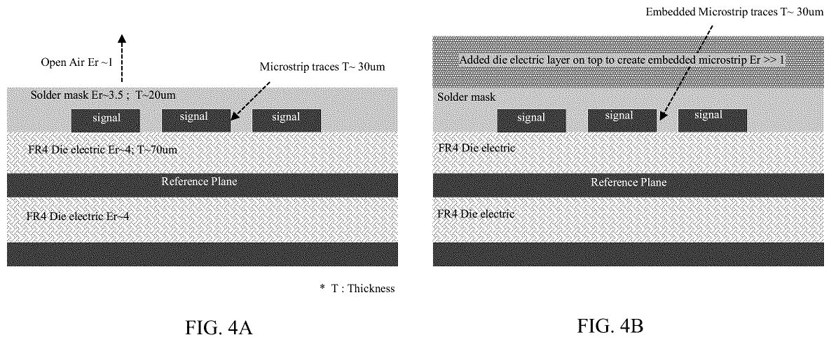

FIG. 4A shows a conventional microstrip stackup while FIG. 4B shows an exemplary embedded microstrip according to an aspect of the present disclosure.

Microstrip routing has inherent high crosstalk because the inductive and capacitive coupling is not properly balanced. The homogeneous strip line structure benefits with balanced inductive and capacitive coupling that helps to cancel the overall far end crosstalk as:

Total channel FEXT=Sum of (inductive FEXT+Capacitive FEXT) (1)

The far end crosstalk is dependent on the difference in propagation delay between even and odd modes, as in Equation (1). Here K is a factor dependent on excitation voltage and stackup.

FEXT≅K (T_{d,e}−T_{d,o}) (2)

Thicker dielectric on top of microstrip leads to lower fringing fields in the air, thus taking the effective dielectric constant close to that of homogenous media. This leads to even- mode and odd-mode propagation velocity being equal which finally leads to FEXT being zero. The trace impedance also decreases now due to higher effective permittivity which leads to higher capacitance.

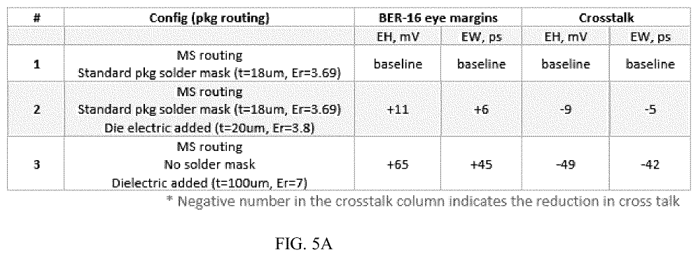

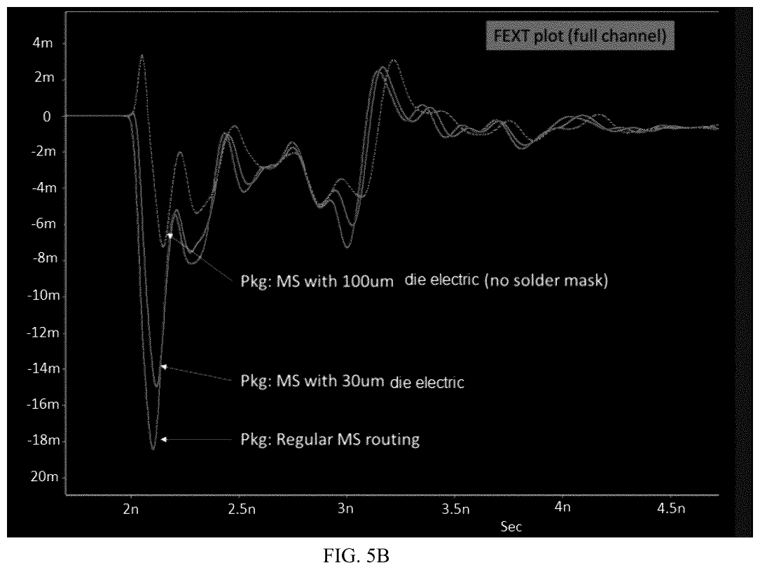

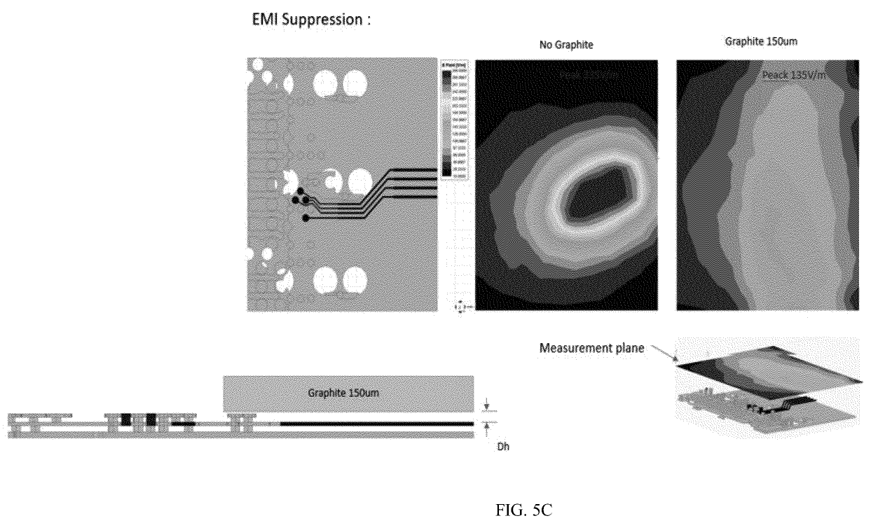

FIGS. 5A to 5C show crosstalk and EMI results of the semiconductor device of FIG. 1.

FIG. 5A shows the analysis for full-channel memory interface at 4800MTs with different package routing configurations to evaluate impact with microstrip routing with underfill on the semiconductor package.

As shown in FIG. 5A, underfill deposition on microstrip routing helps to reduce FEXT significantly. For example, standard underfill coating (Loctite E1172A, Dk=3.8) of 20 um thickness leads to ˜10 mV/5 ps reduction in FEXT. A dielectric material with higher Dk value of 7 (in row 3) can lead to substantial FEXT reduction and margin gains.

The FEXT and corresponding margin gains are directly proportional to die-electric thickness and dielectric constant. A higher Dk value helps change FEXT signature from inductive to capacitive which helps in overall channel crosstalk cancellation. This condition is shown in row 3 in FIG. 5A.

The crosstalk (FEXT) signature comparison for MS routing v/s embedded MS with die electric coated is shown in FIG. 5B, which shows how the FEXT reduces for different scenarios of die-electric addition on MS surface routing.

FIG. 5C shows the electric field reduction on top of the microstrip structure with the presence of graphene material which is not grounded but floating. The plot shows substantial reduction of field strength indicating the EMI reduction with coating above the dielectric layer.

Aspects of the present disclosure may be implemented into a system using any suitable hardware and/or software.

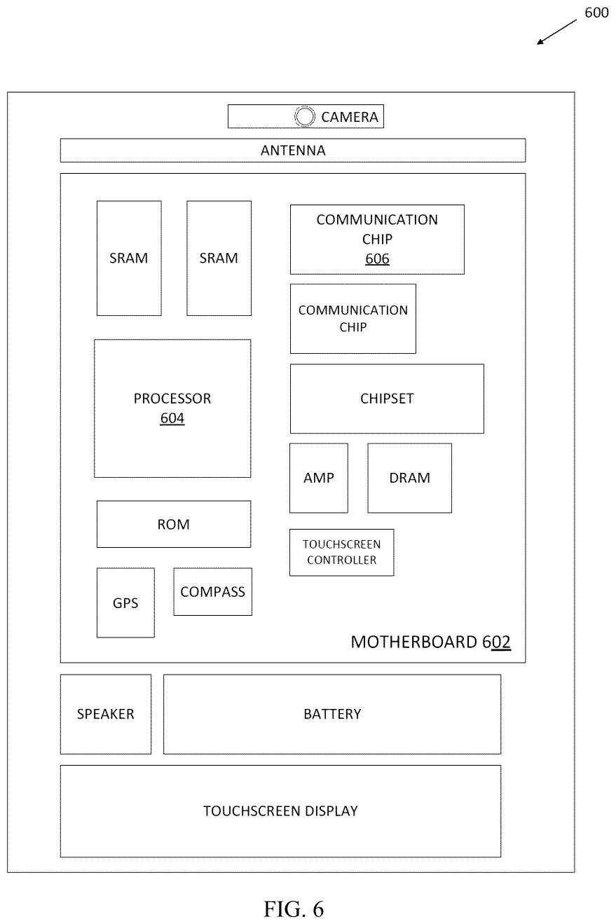

FIG. 6 schematically illustrates a computing device 600 that may include a semiconductor package as described herein, in accordance with some aspects.

As shown in FIG. 6, the computing device 600 may house a board such as a motherboard 602. The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In further implementations, the communication chip 606 may be part of the processor 604.

Depending on its applications, computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 604 of the computing device 600 may be packaged in a semiconductor package, as described herein, and/or other semiconductor devices may be packaged together in a semiconductor package as described herein.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non- solid medium. The term does not imply that the associated devices do not contain any wires, although in some aspects they might not. The communication chip 606 may implement any of a number of wireless standards or protocols, including but not limited to Institute for Electrical and Electronics Engineers (IEEE) standards including Wi-Fi (IEEE 502.11 family), IEEE 502.16standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High Speed Packet Access (HSPA), Evolved HSPA (E- HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), (Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### EXAMPLES

Example 1 may include a device including: a package substrate; a dielectric underfill layer disposed above the package substrate, wherein the package substrate comprises an embedded microstrip layer embedded in the dielectric underfill layer; a semiconductor device embedded in the dielectric underfill layer and electrically coupled to the embedded microstrip of the package substrate; and an electromagnetic interference absorber above a top surface of the semiconductor device, wherein the semiconductor device is electrically coupled to the embedded microstrip layer of the package substrate.

Example 2 may include the device of example 1 and/or any other example disclosed herein, wherein the electromagnetic interference absorber is in contact with the top surface of the semiconductor device.

Example 3 may include the device of example 1 and/or any other example disclosed herein, wherein the electromagnetic interference absorber is not in contact with the top surface of the semiconductor device.

Example 4 may include the device of example 1 and/or any other example disclosed herein, wherein the electromagnetic interference absorber comprises graphene.

Example 5 may include the device of example 1 and/or any other example disclosed herein, wherein the electromagnetic interference absorber is above a top surface of the package substrate.

Example 6 may include the device of example 1 and/or any other example disclosed herein, wherein the embedded microstrip layer is configured for high speed signal routing with the semiconductor device.

Example 7 may include the device of example 1 and/or any other example disclosed herein, wherein the embedded microstrip layer is configured for Double Data Rate (DDR) memory signal routing.

Example 8 may include a method including: providing a package substrate; forming a dielectric underfill layer above the package substrate, wherein the package substrate comprises an embedded microstrip layer embedded in the dielectric underfill layer; embedding a semiconductor device in the dielectric underfill layer and electrically coupling the semiconductor device to the embedded microstrip of the package substrate; and providing an electromagnetic interference absorber above a top surface of the semiconductor device, wherein the semiconductor device is electrically coupled to the embedded microstrip layer of the package substrate.

Example 9 may include the method of example 8 and/or any other example disclosed herein, wherein the electromagnetic interference absorber is in contact with the top surface of the semiconductor device.

Example 10 may include the method of example 8 and/or any other example disclosed herein, wherein the electromagnetic interference absorber is not in contact with the top surface of the semiconductor device.

Example 11 may include the method of example 8 and/or any other example disclosed herein, wherein the electromagnetic interference absorber comprises graphene.

Example 12 may include the method of example 8 and/or any other example disclosed herein, wherein the electromagnetic interference absorber is above a top surface of the package substrate.

Example 13 may include the method of example 8 and/or any other example disclosed herein, wherein the embedded microstrip layer is configured for high speed signal routing with the semiconductor device.

Example 14 may include the method of example 8 and/or any other example disclosed herein, wherein the microstrip routing layer is configured for Double Data Rate (DDR) memory signal routing

Example 15 may include a computing device including: a printed circuit board; and a semiconductor package coupled to the printed circuit board including: a package substrate; a dielectric underfill layer disposed above the package substrate, wherein the package substrate comprises an embedded microstrip layer embedded in the dielectric underfill layer; a semiconductor device embedded in the dielectric underfill layer and electrically coupled to the embedded microstrip of the package substrate; and an electromagnetic interference absorber above a top surface of the semiconductor device, wherein the semiconductor device is electrically coupled to the embedded microstrip layer of the package substrate.

Example 16 may include the computing device of example 15 and/or any other example disclosed herein, wherein the electromagnetic interference absorber is in contact with the top surface of the semiconductor device.

Example 17 may include the computing device of example 15 and/or any other example disclosed herein, wherein the electromagnetic interference absorber is not in contact with the top surface of the semiconductor device.

Example 18 may include the computing device of example 15 and/or any other example disclosed herein, wherein the electromagnetic interference absorber comprises graphene.

Example 19 may include the computing device of example 15 and/or any other example disclosed herein, wherein the electromagnetic interference absorber is above a top surface of the package substrate.

Example 20 may include the computing device of example 15 and/or any other example disclosed herein, wherein the embedded microstrip layer is configured for high speed signal routing with the semiconductor device.

These and other advantages and features of the aspects herein disclosed will be apparent through reference to the following description and the accompanying drawings. Furthermore, it is to be understood that the features of the various aspects described herein are not mutually exclusive and can exist in various combinations and permutations.

It will be understood that any property described herein for a specific system or device may also hold for any system or device described herein. It will also be understood that any property described herein for a specific method may hold for any of the methods described herein. Furthermore, it will be understood that for any device, system, or method described herein, not necessarily all the components or operations described will be enclosed in the device, system, or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a package substrate;
a dielectric underfill layer disposed above the package substrate, wherein the package substrate comprises an embedded microstrip layer embedded in the dielectric underfill layer;
a semiconductor device embedded in the dielectric underfill layer and electrically coupled to the embedded microstrip of the package substrate; and
an electromagnetic interference absorber above a top surface of the semiconductor device, wherein the semiconductor device is electrically coupled to the embedded microstrip layer of the package substrate.

2. The device of claim 1, wherein the electromagnetic interference absorber is in contact with the top surface of the semiconductor device.

3. The device of claim 1, wherein the electromagnetic interference absorber is not in contact with the top surface of the semiconductor device.

4. The device of claim 1, wherein the electromagnetic interference absorber comprises graphene.

5. The device of claim 1, wherein the electromagnetic interference absorber is above a top surface of the package substrate.

6. The device of claim 1, wherein the embedded microstrip layer is configured for high speed signal routing with the semiconductor device.

7. The device of claim 1, wherein the embedded microstrip layer is configured for Double Data Rate (DDR) memory signal routing.

8. A method comprising:
providing a package substrate;
forming a dielectric underfill layer above the package substrate, wherein the package substrate comprises an embedded microstrip layer embedded in the dielectric underfill layer;
embedding a semiconductor device in the dielectric underfill layer and electrically coupling the semiconductor device to the embedded microstrip of the package substrate; and
providing an electromagnetic interference absorber above a top surface of the semiconductor device, wherein the semiconductor device is electrically coupled to the embedded microstrip layer of the package substrate.

9. The method of claim 8, wherein the electromagnetic interference absorber is in contact with the top surface of the semiconductor device.

10. The method of claim 8, wherein the electromagnetic interference absorber is not in contact with the top surface of the semiconductor device.

11. The method of claim 8, wherein the electromagnetic interference absorber comprises graphene.

12. The method of claim 8, wherein the electromagnetic interference absorber is above a top surface of the package substrate.

13. The method of claim 8, wherein the embedded microstrip layer is configured for high speed signal routing with the semiconductor device.

14. The method of claim 8, wherein the microstrip routing layer is configured for Double Data Rate (DDR) memory signal routing.

15. A computing device comprising:
a printed circuit board; and
a semiconductor package coupled to the printed circuit board comprising:
a package substrate;
a dielectric underfill layer disposed above the package substrate, wherein the package substrate comprises an embedded microstrip layer embedded in the dielectric underfill layer;
a semiconductor device embedded in the dielectric underfill layer and electrically coupled to the embedded microstrip of the package substrate; and
an electromagnetic interference absorber above a top surface of the semiconductor device, wherein the semiconductor device is electrically coupled to the embedded microstrip layer of the package substrate.

16. The computing device of claim 15, wherein the electromagnetic interference absorber is in contact with the top surface of the semiconductor device.

17. The computing device of claim 15, wherein the electromagnetic interference absorber is not in contact with the top surface of the semiconductor device.

18. The computing device of claim 15, wherein the electromagnetic interference absorber comprises graphene.

19. The computing device of claim 15, wherein the electromagnetic interference absorber is above a top surface of the package substrate.

20. The computing device of claim 15, wherein the embedded microstrip layer is configured for high speed signal routing with the semiconductor device.
